(19) United States
(12) Patent Application Publication
(10) Pub. No.: US 2003/0089949 A1
(43) Pub. Date: May 15, 2003

(54) Thin film transistor crystal liquid display devices with convex structure and manufacturing method thereof

(75) Inventors: Wen-Jian Lin, Hsinchu (TW); Hung-Huei Hsu, Hsinchu (TW); Hong-Da Liu, Hsinchu (TW); Wen-Chung Tant, Hsinchu (TW)

Correspondence Address: VOLPE AND KOENIG, P.C., SUITE 400, ONE PENN CENTER, 1617 JOHN F. KENNEDY BOULEVARD, PHILADELPHIA, PA, 19103, US

(73) Assignee: Prime View International Co. Ltd., Hsinchu (TW)

(21) Appl. No.: 10/138,626

(22) Filed: May 3, 2002

(30) Foreign Application Priority Data
Nov. 9, 2001 (TW) 90127954

(51) Int. Cl. G02F 1/136; H01L 21/00; H01L 27/01; H01L 31/0392

(52) U.S. Cl. 257/347; 438/151; 257/350; 438/155

(57) ABSTRACT

A structure of a thin film transistor (TFT) liquid crystal display (LCD) device with a convex structure and a manufacturing method thereof are provided. The manufacturing method includes steps of: providing an insulation substrate; forming a first conductor layer on the insulation substrate; removing portions of the first conductor layer to define a first conductor structure and a first convex structure, wherein the first convex structure is posited on an area of pixel; forming an insulation layer and a semiconductor layer sequentially on the first conductor structure and the insulation substrate having the first conductor layer; removing portions of the semiconductor layer to define a semiconductor structure; forming a second conductor layer on the semiconductor structure; and removing portions of the second conductor layer to define a second conductor structure.

### FIELD OF THE INVENTION

This invention relates to a thin film transistor crystal liquid display device with a convex structure, and more particularly to a reflective type or translucent type thin film transistor crystal liquid display device.

### BACKGROUND OF THE INVENTION

Because of the progress of the manufacturing technology, the liquid crystal display (LCD) becomes an extensively used display component. The display theory of LCD is to use an electric field to control the arranging condition of crystal molecules and whether the crystal molecules can pass through or not decides the bright or dark effect of the monitor. Thus, for LCD, how to obtain the brighter displaying effect is still an important research subject now.

For the reflective type or transparent type thin film transistor crystal display (TFT-LCD), the brightness is decided by the incident and reflective light of the illuminant. Therefore, for obtaining a brighter display effect, it is necessary to increase the light scattering intensity in the direction perpendicular to the display screen. To reach the purpose described above, it is needed to make a reflector having an optimum reflective characteristic. Thus, a resin layer 114 including a plurality of transparent resin beads 113 is formed on a first transparent electrode plate 111 (as shown in FIG. 1A), so that when a light passes through a color filter 112 and said first transparent electrode plate 111 to enter said resin layer 114, said light will be offset owing to impact with said plurality of transparent resin beads 113. Then, through the electric field effect between the second transparent electrode plate 116 and the first transparent electrode plate 111 formed on the array plate 115 of TFT, the crystal molecules will produce the light scattering, and the scattered light will be reflected by the reflector 117. The advantage of the method described above is about increasing the light scattering angle to control the reflection direction indirectly. However, the disadvantage of this method is that the purpose of exactly controlling the scattering direction through adjusting the positions of the plurality of transparent beads 113 is difficult to achieve.

Because of the shortcomings described above, a manufacturing process of growing a resin layer 124 directly onto the second transparent electrode plate 126 on the array plate 125 of TFT is proposed (as shown in FIG. 1B). Thus, when a light passes through said color filter 122, the crystal molecules will produce the light scattering via the electric field effect between the second transparent electrode plate 126 and the first transparent electrode plate 122, and said resin layer 124 will reflect said scattering light later. Because the structure of said resin layer 124 is crooked, the uneven surface can be used to control the angle of reflection. Consequently, the reflection direction can be controlled effectively.

Although prior arts disclose forming a resin layer to increase the light scattering intensity in the direction perpendicular to the display screen, the manufacturing cost raises relatively and the manufacturing technology becomes more complicate (since a photo-masking is added), too. Thus, the main emphasis of the present invention is how to economize the cost and simplify the manufacturing technology, but still can reach the purpose described above.

Because of the technical defects described above, the applicant keeps on carving unflaggingly to develop “the structure of a thin film transistor crystal liquid display device with a convex structure and the manufacturing method thereof” through wholehearted experience and research.

### SUMMARY OF THE INVENTION

It is an object of the present invention to provide a structure of a TFT-LCD with a convex structure and the manufacturing method thereof to dispense with the expensive material cost and complicated manufacturing technology in the prior arts.

It is another object of the present invention to provide a method for manufacturing TFT-LCD with a convex structure, and the method can simplify the manufacturing steps and economize the cost.

It is another further object of the present invention to provide a structure of a TFT-LCD with a convex structure that has the same usage of the prior arts but the manufacturing steps of the structure are less than those of prior arts.

The present invention provides a method for manufacturing a thin film transistor (TFT) liquid crystal display (LCD) device with a convex structure. The method comprises steps of: (a) providing an insulation substrate; (b) forming a first conductor layer on the insulation substrate; (c) removing portions of the first conductor layer to define a first conductor structure and a first convex structure, wherein the first convex structure is posited on an area of pixel; (d) forming an insulation layer and a semiconductor layer sequentially on the first conductor structure and the insulation substrate having the first conductor layer; (e) removing portions of the semiconductor layer to define a semiconductor structure; (f) forming a second conductor layer on the semiconductor structure; and (g) removing portions of the second conductor layer to define a second conductor structure.

Preferably, the thin film transistor liquid crystal display is one of a reflective type and a translucent type thin film transistor liquid crystal display device.

Preferably, the first conductor layer is a metallic layer.

Preferably, the taper angle of the first convex structure is ranged from three to twenty degrees.

Preferably, the second conductor layer is a metallic layer.

Preferably, the step (e) comprises the step of (e1) defining the semiconductor structure and a second convex structure at the same time. The convex portion of the second convex structure is corresponding to the convex portion of the first convex structure, and the surface area of the convex portion of the second convex structure is smaller than that of the first convex structure.

Preferably, the step (g) comprises the step of (g1) defining the second conductor structure and a third convex structure at the same time. The convex portion of the third convex structure is corresponding to the convex portion of the second convex structure, and the surface area of the convex portion of the third convex structure is smaller than that of the second convex structure.

Preferably, the taper angles of the second and third convex structures are ranged from three to twenty degrees.

In accordance with an aspect of the present invention, a thin film transistor (TFT) liquid crystal display (LCD) device with a convex structure is disclosed. The TFT-LCD comprises: an insulation substrate; a first conductor structure and a first convex structure formed on the insulation substrate, wherein the first convex structure is posited on an area of pixel; an insulation layer formed on the first conductor structure and the first convex structure; a semiconductor structure formed on the insulation layer; and a second conductor structure formed on the semiconductor structure.

Preferably, the thin film transistor liquid crystal display is one of a reflective type and a translucent type thin film transistor liquid crystal display device.

Preferably, the first and second conductor structures are metallic structures.

Preferably, the taper angle of the first convex structure is ranged from three to twenty degrees.

Preferably, the semiconductor structure and a second convex structure are formed at the same time. The convex portion of the second convex structure is corresponding to the convex portion of the first convex structure, and the surface area of the convex portion of the second convex structure is smaller than that of the first convex structure.

Preferably, the second conductor structure and a third convex structure are formed at the same time. The convex portion of the third convex structure is corresponding to the convex portion of the second convex structure, and the surface area of the convex portion of the third convex structure is smaller than that of the second convex structure.

Preferably, the taper angles of the second and third convex structures are ranged from three to twenty degrees.

In accordance with an aspect of the present invention, a method for manufacturing a thin film transistor (TFT) liquid crystal display (LCD) device with a convex structure is disclosed. The method comprises steps of: (a) providing an insulation substrate; (b) forming a conductor layer on the insulation substrate; (c) removing portions of the conductor layer to define a conductor structure and a first convex structure, wherein the first convex structure is posited on an area of pixel; (d) forming a first insulation layer and a first conductor layer sequentially on the conductor structure and the insulation substrate having the conductor structure; (e) removing portions of the first conductor structure to define a first conductor structure; (f) forming a second insulation layer on the first conductor structure; (g) removing portions of the first insulation layer and the second insulation layer to define a first channel and a second channel; (h) forming a second conductor layer on the second insulation layer; and (i) removing the second conductor layer to define a second conductor structure.

Preferably, the thin film transistor liquid crystal display is one selected from a group consisting of a low temperature ploysilicon reflective type thin film transistor liquid crystal display (LTPS TFT-LCD) device, a reflective type thin film transistor liquid crystal display device, and a translucent type thin film transistor liquid crystal display device.

Preferably, the semiconductor layer is a polysilicon (P-Si) layer.

Preferably, the step (f) comprises the step of (f1) defining the first conductor structure and a second convex structure at the same time. The convex portion of the second convex structure is corresponding to the convex portion of the first convex structure, and the surface area of the convex portion of the second convex structure is smaller than that of the first convex structure.

Preferably, the step (i) comprises the step of (i1) defining the second conductor structure and a third convex structure at the same time. The convex portion of the third convex structure is corresponding to the convex portion of the second convex structure, and the surface area of the convex portion of the third convex structure is smaller than that of the second convex structure.

In accordance with an aspect of the present invention, a thin film transistor (TFT) liquid crystal display (LCD) device with a convex structure is disclosed. The TFT-LCD comprises: an insulation substrate; a semiconductor structure and a first convex structure formed on the insulation substrate, wherein the first convex structure is posited on an area of pixel; a first insulation layer formed on the semiconductor structure and the first convex structure; a first conductor structure and a second convex structure formed on the first insulation layer; a second insulation layer formed on the first conductor layer and the second convex structure, wherein the first insulation layer and the second insulation layer are etched to define a first channel and a second channel; and a second conductor structure and a third convex structure formed on the second insulation layer.

Preferably, the thin film transistor liquid crystal display is one selected from a group consisting of a low temperature polysilicon reflective type thin film transistor liquid crystal display (LTPS TFT-LCD) device, a reflective type thin film transistor liquid crystal display device, and a translucent type thin film transistor liquid crystal display.

Preferably, the semiconductor structure and a second convex structure are formed at the same time. The convex portion of the second convex structure is corresponding to the convex portion of the first convex structure, and the surface area of the convex portion of the second convex structure is smaller than that of the first convex structure.

Preferably, the second conductor structure and a third convex structure are formed at the same time. The convex portion of the third convex structure is corresponding to the convex portion of the second convex structure, and the surface area of the convex portion of the third structure is smaller than that of the second convex structure.

In accordance with an aspect of the present invention, a method for manufacturing a thin film transistor (TFT) liquid crystal display (LCD) device with a convex structure is disclosed. The method comprises steps of: (a) providing an insulation substrate; and (b) forming a multi-layer stack convex structure, a thin film transistor structure, and a transparent electrode structure on the insulation substrate, wherein the transparent electrode layer is connected to the source/drain region of the thin film transistor structure.

Preferably, the film transistor liquid crystal display is one selected from a group consisting of a reflective type thin film transistor liquid crystal display device, a translucent type thin film transistor liquid crystal display, and a low temperature ploysilicon reflective type thin film transistor liquid crystal display (LTPS TFT-LCD) device.

In accordance with an aspect of the present invention, a thin film transistor (TFT) liquid crystal display (LCD) device with a convex structure is disclosed. The TFT-LCD comprises: an insulation substrate; a multi-layer stack convex structure formed on the insulation substrate; a thin film transistor structure formed on the insulation substrate; and a transparent electrode structure formed on the insulation substrate, wherein the transparent electrode structure is connected to the source/drain region of the thin film transistor structure.

Preferably, the thin film transistor liquid crystal display is one selected from a group consisting of a reflective type thin film transistor liquid crystal display device, a translucent type thin film transistor liquid crystal display device, and a low temperature ploysilicon reflective type thin film transistor liquid crystal display (LTPS TFT-LCD) device.

The above objects and advantages of the present invention will become more readily apparent to those ordinarily skilled in the art after reviewing the following detailed descriptions and accompanying drawings, in which:

### BRIEF DESCRIPTION OF THE DRAWINGS

FIGS. 1A˜1B are schematical views showing the TFT-LCD with a resin layer formed on the transparent electrode plate in the prior art;

FIGS. 2A˜2G are schematical views showing the manufacturing methods and steps of TFT-LCD according to the present invention;

FIGS. 3A˜3I are schematical views showing the manufacturing methods and steps of LTPS TFT-LCD in a preferred embodiment according to the present invention;

FIGS. 4A1˜4A3 show the diameter/thickness list, the top view and the side view of the convex structure of TFT-LCD in a first preferred embodiment according to the present invention;

FIGS. 4B1˜4B3 show the diameter/thickness list, the top view and the side view of the convex structure of TFT-LCD in a second preferred embodiment according to the present invention;

FIGS. 4C1˜4C3 show the diameter/thickness list, the top view and the side view of the convex structure of TFT-LCD in a third preferred embodiment according to the present invention; and

FIGS. 4D1˜4D3 show the diameter/thickness list, the top view and the side view of the convex structure of TFT-LCD in a fourth preferred embodiment according to the present invention.

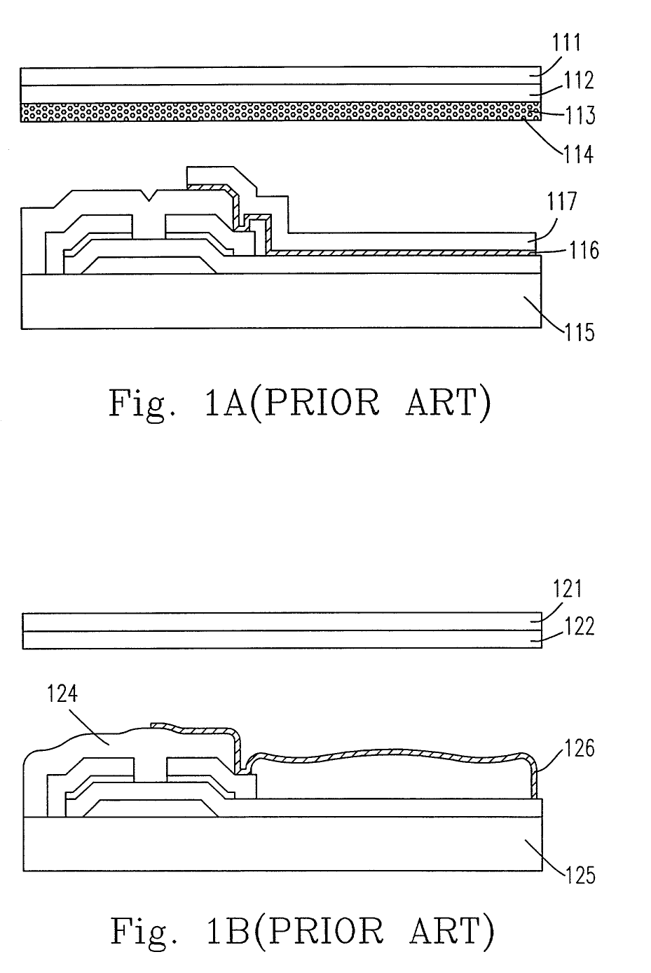

### DETAILED DESCRIPTION OF THE PREFERRED EMBODIMENT

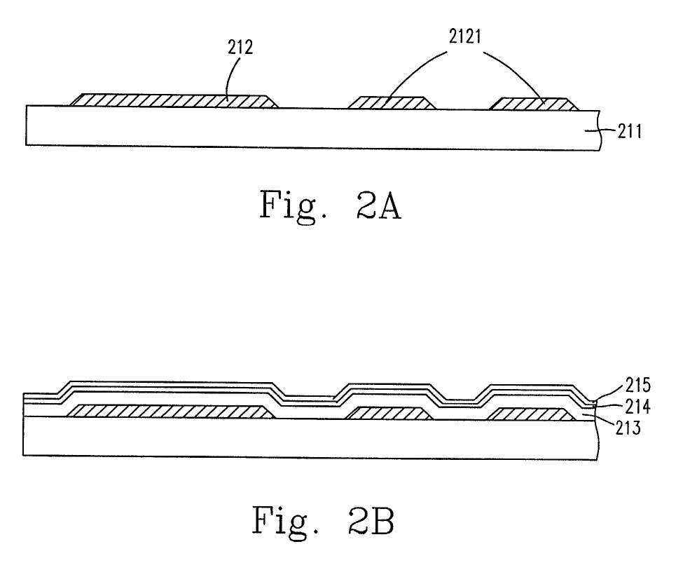

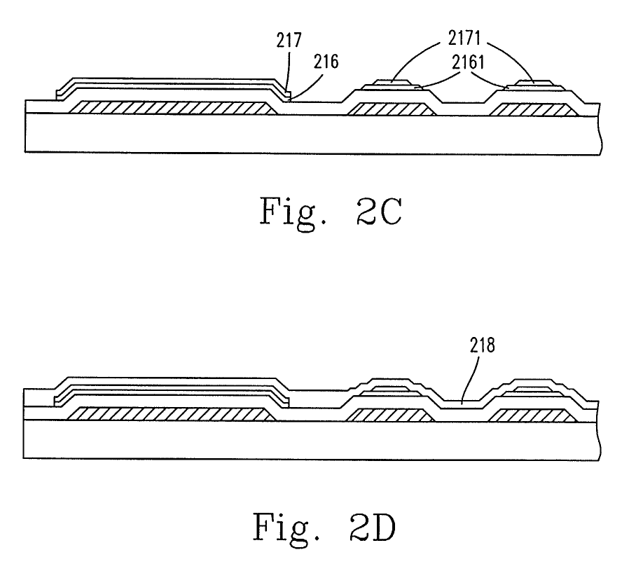

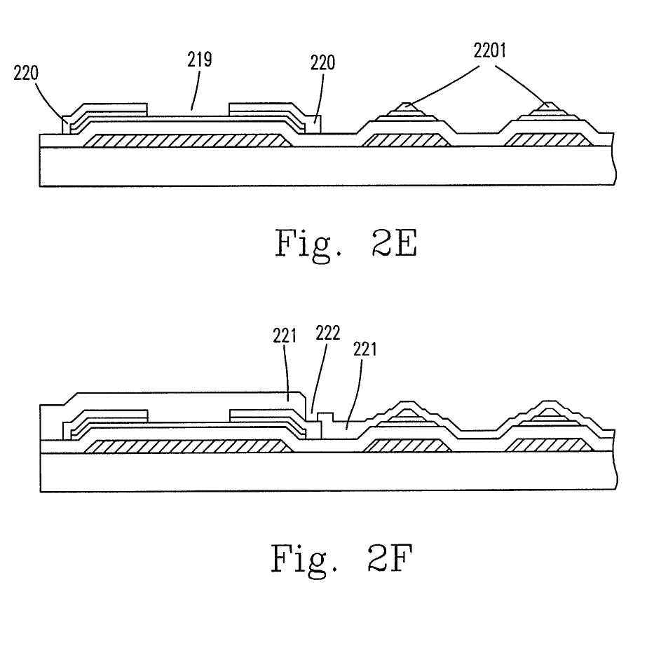

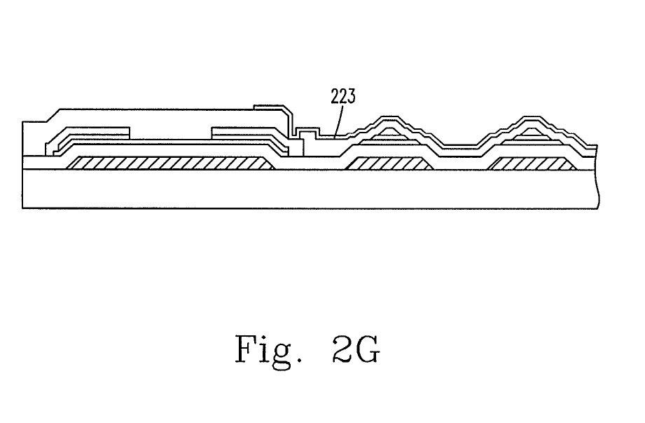

Please refer to FIG. 2 schematically showing the manufacturing methods and steps of TFT-LCD according to the present invention for improving the known methods. As shown in FIG. 2A, after forming a first conductor layer (which can be accomplished by chromium, tungsten molybdate, tantalum, aluminum, or copper and can be the gate conductor layer of the thin film transistor crystal liquid) on an insulation substrate 211, the first photolithography and etching process defines a first conductor structure 212 and a first convex structure 2121, and the first convex structure 2121 is posited on an area of pixel. Subsequently, an insulation layer 213, a semiconductor layer 214 (generally being an amorphous layer (A-Si)), and a heavily doped semiconductor layer 215 (generally being an N+ amorphous layer (N+A-Si)) are sequentially formed from bottom to top, as shown in FIG. 2B. Then, as shown in FIG. 2C, the second photolithography and etching process defines a semiconductor structure 216, a heavily doped semiconductor structure 217, and a second convex structure 2161 and 2171, and the convex portion of the second convex structure 2161 and 2171 which corresponds to that of the first convex structure 2121. The surface area of the convex portion of the second convex structure 2161 and 2171 is smaller than that of the first convex structure 2121. Then, FIG. 2D shows the further deposition of a second conductor layer, and then, as shown in FIG. 2E, the third photolithography and etching process defines a second conductor structure 220 and a third convex structure 2201. And the convex portion of the third convex structure 2201 is corresponding to that of the second convex structure 2161 and 2171. Also, the surface area of the convex portion of the third convex structure 2201 is smaller than that of the second convex structure 2161, and there is formed a channel structure 219 between the heavily doped semiconductor structure 217 and the second conductor structure 220 to form on the second conductor a source/drain region. FIG. 2F shows that after forming a protection layer (generally being a silicon nitride layer) 221 on the source/drain region, the fourth photolithography and etching process defines a contact window structure 222. Then, FIG. 2G shows the deposition of a transparent electrode layer (generally being indium tin oxide (ITO)), and then the fifth photolithography and etching process defines a transparent electrode pixel area 223.

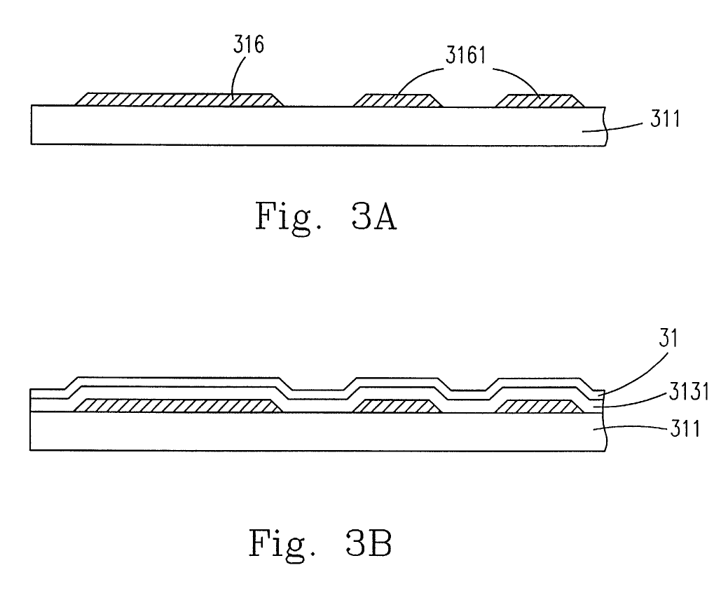

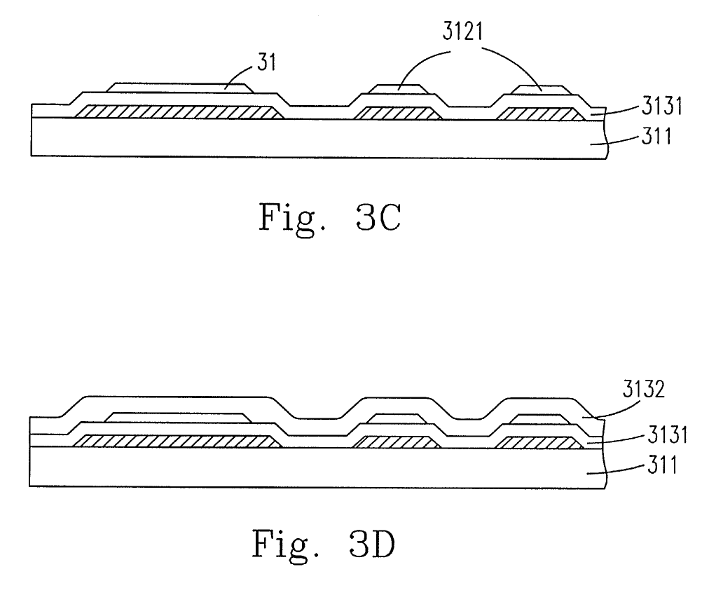

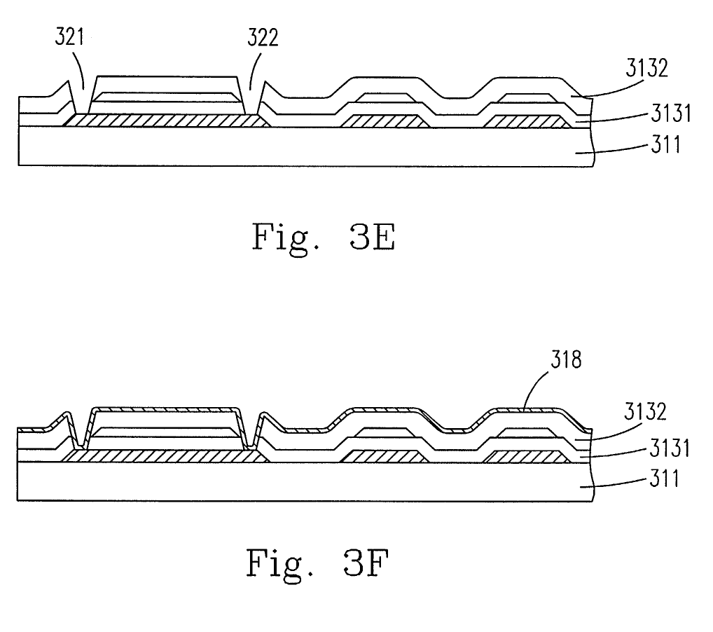

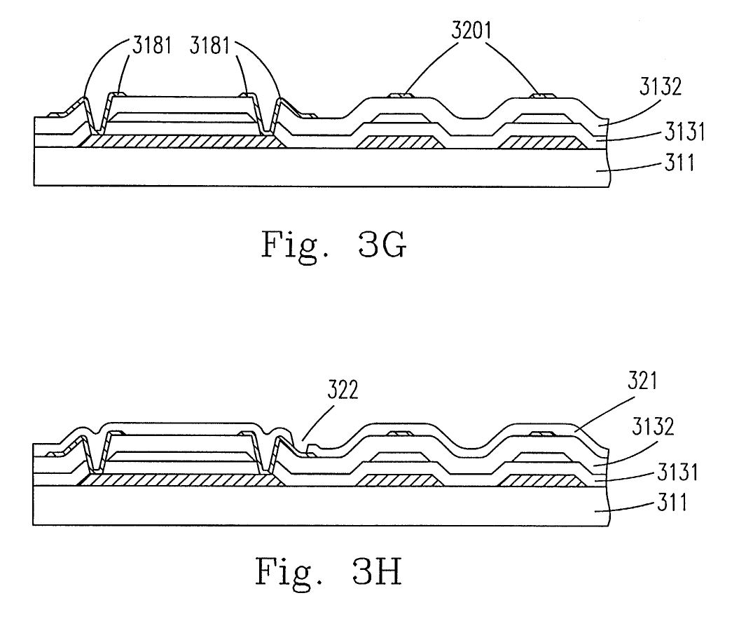

Please refer to FIG. 3 schematically showing the manufacturing methods and steps of LTPS TFT-LCD in another preferred embodiment according to the present invention. As shown in FIG. 3A, after forming a semiconductor layer (generally being a polysilicon layer) on an insulation substrate 311, the first photolithography and etching process defines a semiconductor structure 316 and a first convex structure 3161, and the first convex structure 3161 is posited on an area of pixel. Subsequently, a first insulation layer 3131 and a first conductor layer 31 (which can be accomplished by chromium, tungsten molybdate, tantalum, aluminum, or copper and can be the gate conductor layer of the thin film transistor crystal liquid) are sequentially formed from bottom to top, as shown in FIG. 3B. FIG. 3C shows the second photolithography and etching process defining a first conductor structure 312 and a second convex structure 3121, and the convex portion of the second convex structure 3121 is corresponding to that of the first convex structure 3161. The surface area of the convex portion of the second convex structure 3121 is smaller than that of the first convex structure 3161. FIG. 3D shows further depositing a second insulation layer 3132, and then FIG. 3E shows the third photolithography and etching process removing portions of the first insulation layer 3131 and the second insulation layer 3132 to define a first channel 321 and a second channel 322. Now, refer to FIG. 3F showing a second conductor layer 318 further formed on the second insulation layer 3132. Then, as shown in FIG. 3G, the fourth photolithography and etching process defines a second conductor structure 3181 and a third convex structure 3201, and the convex portion of the third convex structure 3201 is corresponding to that of the second convex structure 3121. The surface area of the convex portion of the third convex structure 3201 is smaller than that of the second convex structure 3121. As shown in FIG. 3H, after forming a protection layer (generally being a silicon nitride layer) 321 on the second conductor structure 3181 and the third convex structure 3201, the fifth photolithography and etching process defines a contact window structure 322. Then, FIG. 31 shows that after depositing a transparent electrode layer (generally being indium tin oxide (ITO)), the sixth photolithography and etching process defines a transparent electrode pixel area 323.

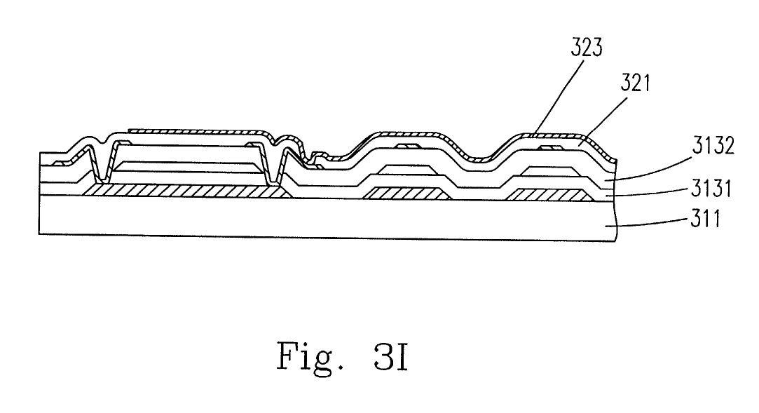

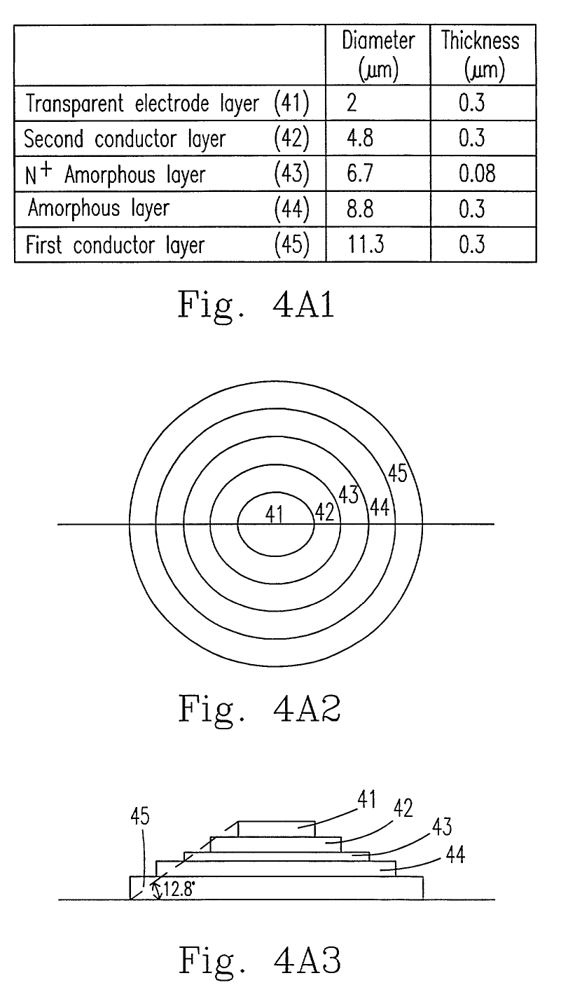

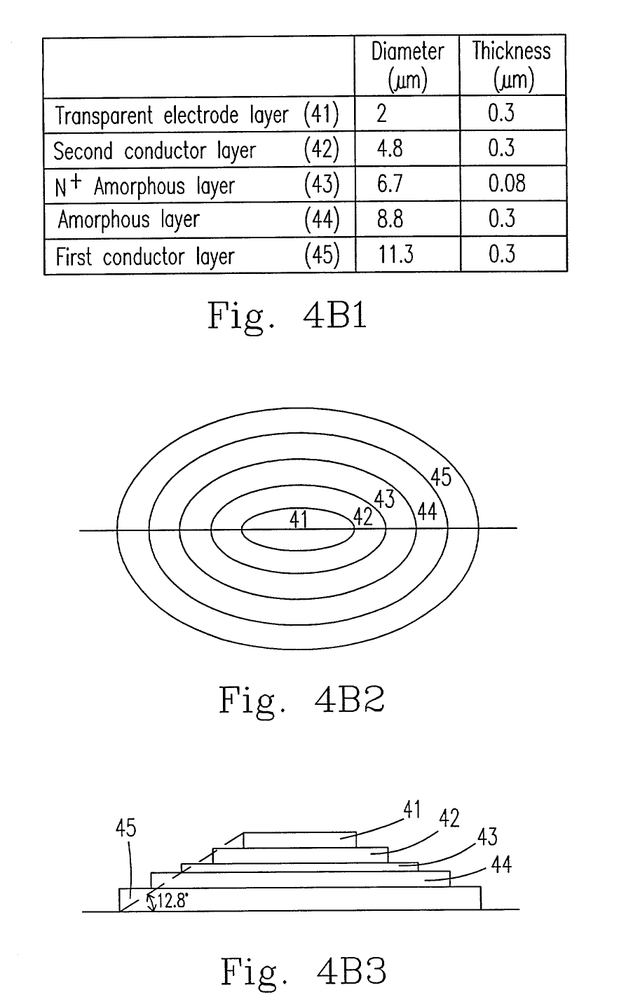

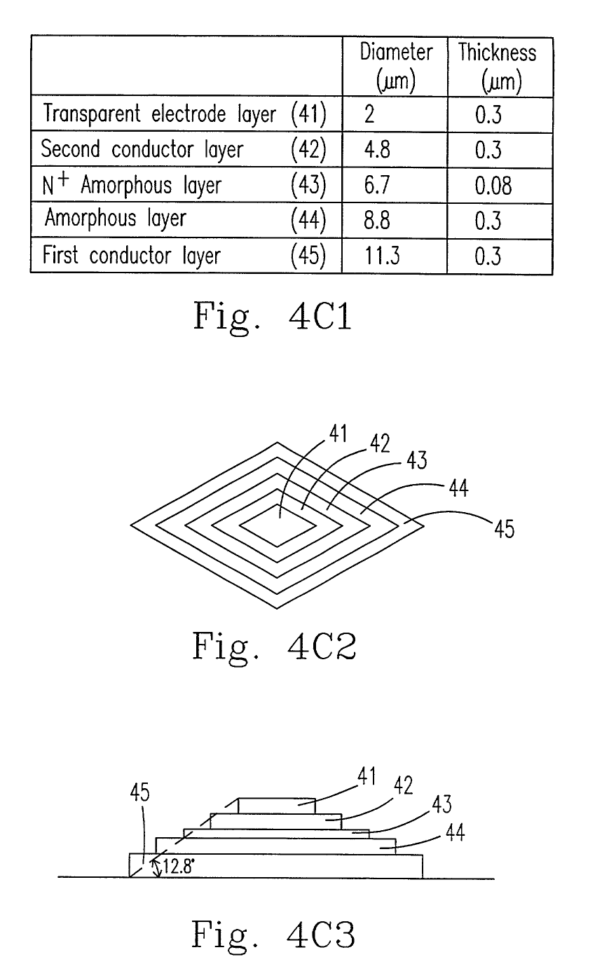

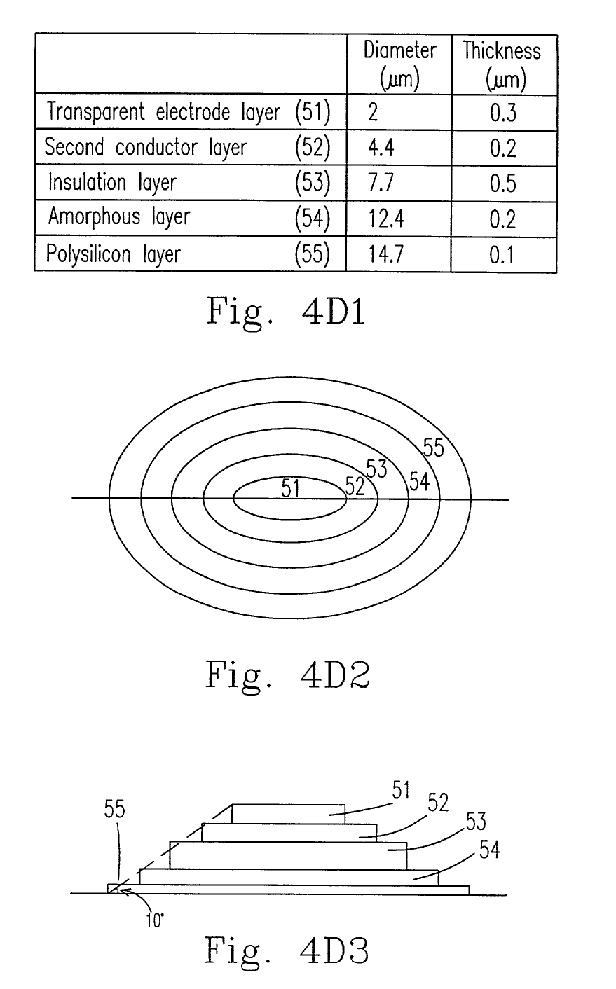

Another advantage of the present invention is that the first conductor layer and second conductor layer both can be a metallic layer, and the first convex structure, the second convex structure, and the third convex structure all have a plurality of convex portions. Also, the taper angle will be changed with the control of the etching concentration, time, and temperature . . . , but still ranged from three to twenty degrees. The list in FIGS. 4A1˜4D1 show the convex structures being formed by different kinds of deposition diameter and pattern thickness. The top views in FIGS. 4A2˜4D2 show more different shapes of the convex structures, and the side views in FIGS. 4A3˜4D3 show the changes of the taper angle caused by different kinds of deposition diameters and pattern thicknesses.

As described above, compared to the prior arts in the TFT-LCD field, the present invention has a multi-layer stack convex structure that can control the reflection angle by the specific taper angle and can effectively control the light reflection direction. The multi-layer stack convex structure is posited on the area of pixel simultaneously, when the structure of thin film transistor is formed. Thus, compared to the prior arts, the manufacturing steps of the present invention are simple, especially the manufacturing method in the present invention can save one photo-masking process and dispense with the expensive resin, so that the cost can be further minimized. Consequently, the present invention conforms to the demand of the industry and owns inventiveness.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A method for manufacturing a thin film transistor (TFT) liquid crystal display (LCD) device with a convex structure, comprising steps of:
(a) providing an insulation substrate;
(b) forming a first conductor layer on said insulation substrate;
(c) removing portions of said first conductor layer to define a first conductor structure and a first convex structure, wherein said first convex structure is posited on an area of pixel;
(d) forming an insulation layer and a semiconductor layer sequentially on said first conductor structure and said insulation substrate having said first conductor layer;
(e) removing portions of said semiconductor layer to define a semiconductor structure;
(f) forming a second conductor layer on said semiconductor structure; and
(g) removing portions of said second conductor layer to define a second conductor structure.

2. A method according to claim 1 wherein said thin film transistor liquid crystal display is one of a reflective type and a translucent type thin film transistor liquid crystal display device.

3. A method according to claim 1 wherein said first conductor layer is a metallic layer.

4. A method according to claim 1 wherein the taper angle of said first convex structure is ranged from three to twenty degrees.

5. A method according to claim 1 wherein said second conductor layer is a metallic layer.

6. A method according to claim 1 wherein said step (e) comprises the step of
(e1) defining said semiconductor structure and a second convex structure at the same time, wherein said convex portion of said second convex structure is corresponding to said convex portion of said first convex structure, and said surface area of said convex portion of said second convex structure is smaller than that of said first convex structure.

7. A method according to claim 6 wherein said step (g) comprises the step of (g1) defining said second conductor structure and a third convex structure at the same time, wherein said convex portion of said third convex structure is corresponding to said convex portion of said second convex structure, and said surface area of said convex portion of said third convex structure is smaller than that of said second convex structure.

8. A method according to claim 7 wherein the taper angles of said second and third convex structures are ranged from three to twenty degrees.

9. A thin film transistor (TFT) liquid crystal display (LCD) device with a convex structure, comprising:
an insulation substrate;
a first conductor structure and a first convex structure formed on said insulation substrate, wherein said first convex structure is posited on an area of pixel;
an insulation layer formed on said first conductor structure and said first convex structure;
a semiconductor structure formed on said insulation layer; and
a second conductor structure formed on said semiconductor structure.

10. A device according to claim 9 wherein said thin film transistor liquid crystal display is one of a reflective type and a translucent type thin film transistor liquid crystal display device.

11. A device according to claim 10 wherein said first and second conductor structures are metallic structures.

12. A device according to claim 10 wherein the taper angle of said first convex structure is ranged from three to twenty degrees.

13. A device according to claim 10 wherein said semiconductor structure and a second convex structure are formed at the same time, wherein said convex portion of said second convex structure is corresponding to said convex portion of said first convex structure, and said surface area of said convex portion of said second convex structure is smaller than that of said first convex structure.

14. A device according to claim 13 wherein said second conductor structure and a third convex structure are formed at the same time, wherein said convex portion of said third convex structure is corresponding to said convex portion of said second convex structure, and said surface area of said convex portion of said third convex structure is smaller than that of said second convex structure.

15. A device according to claim 14 wherein the taper angles of said second and third convex structures are ranged from three to twenty degrees.

16. A method for manufacturing a thin film transistor (TFT) liquid crystal display (LCD) device with a convex structure, comprising steps of:
(a) providing an insulation substrate;
(b) forming a conductor layer on said insulation substrate;
(c) removing portions of said conductor layer to define a conductor structure and a first convex structure, wherein said first convex structure is posited on an area of pixel;
(d) forming a first insulation layer and a first conductor layer sequentially on said conductor structure and said insulation substrate having said conductor structure;
(e) removing portions of said first conductor structure to define a first conductor structure;
(f) forming a second insulation layer on said first conductor structure;
(g) removing portions of said first insulation layer and said second insulation layer to define a first channel and a second channel;
(h) forming a second conductor layer on said second insulation layer; and
(i) removing said second conductor layer to define a second conductor structure.

17. A method according to claim 16 wherein said thin film transistor liquid crystal display is one selected from a group consisting of a low temperature ploysilicon reflective type thin film transistor liquid crystal display (LTPS TFT-LCD) device, a reflective type thin film transistor liquid crystal display device, and a translucent type thin film transistor liquid crystal display device.

18. A method according to claim 16 wherein said semiconductor layer is a polysilicon (P-Si) layer.

19. A method according to claim 16 wherein said step (f) comprises the step of (f1) defining said first conductor structure and a second convex structure at the same time, wherein said convex portion of said second convex structure is corresponding to said convex portion of said first convex structure, and said surface area of said convex portion of said second convex structure is smaller than that of said first convex structure.

20. A method according to claim 16 wherein said step (i) comprises the step of (i1) defining said second conductor structure and a third convex structure at the same time, wherein said convex portion of said third convex structure is corresponding to said convex portion of said second convex structure, and said surface area of said convex portion of said third convex structure is smaller than that of said second convex structure.

21. A thin film transistor (TFT) liquid crystal display (LCD) device with a convex structure, comprising:
an insulation substrate;
a semiconductor structure and a first convex structure formed on said insulation substrate, wherein said first convex structure is posited on an area of pixel;
a first insulation layer formed on said semiconductor structure and said first convex structure;
a first conductor structure and a second convex structure formed on said first insulation layer;
a second insulation layer formed on said first conductor layer and said second convex structure, wherein said first insulation layer and said second insulation layer are etched to define a first channel and a second channel; and
a second conductor structure and a third convex structure formed on said second insulation layer.

22. A device according to claim 21 wherein said thin film transistor liquid crystal display is one selected from a group consisting of a low temperature polysilicon reflective type thin film transistor liquid crystal display (LTPS TFT-LCD) device, a reflective type thin film transistor liquid crystal display device, and a translucent type thin film transistor liquid crystal display.

23. A device according to claim 21 wherein said semiconductor structure and a second convex structure are formed at the same time, wherein said convex portion of said second convex structure is corresponding to said convex portion of said first convex structure, and said surface area of said convex portion of said second convex structure is smaller than that of said first convex structure.

24. A device according to claim 21 wherein said second conductor structure and a third convex structure are formed at the same time, wherein said convex portion of said third convex structure is corresponding to said convex portion of said second convex structure, and said surface area of said convex portion of said third structure is smaller than that of said second convex structure.

25. A method for manufacturing a thin film transistor (TFT) liquid crystal display (LCD) device with a convex structure, comprising steps of:
(a) providing an insulation substrate; and
(b) forming a multi-layer stack convex structure, a thin film transistor structure, and a transparent electrode structure on said insulation substrate, wherein said transparent electrode layer is connected to said source/drain region of said thin film transistor structure.

26. A manufacturing method according to claim 45 wherein said thin film transistor liquid crystal display is one selected from a group consisting of a reflective type thin film transistor liquid crystal display device, a translucent type thin film transistor liquid crystal display, and a low temperature ploysilicon reflective type thin film transistor liquid crystal display (LTPS TFT-LCD) device.

27. A thin film transistor (TFT) liquid crystal display (LCD) device with a convex structure, comprising:
an insulation substrate;
a multi-layer stack convex structure formed on said insulation substrate;
a thin film transistor structure formed on said insulation substrate; and
a transparent electrode structure formed on said insulation substrate, wherein said transparent electrode structure is connected to said source/drain region of said thin film transistor structure.

28. A device according to claim 27 wherein said thin film transistor liquid crystal display is one selected from a group consisting of a reflective type thin film transistor liquid crystal display device, a translucent type thin film transistor liquid crystal display device, and a low temperature ploysilicon reflective type thin film transistor liquid crystal display (LTPS TFT-LCD) device.
